(19) United States
(12) Patent Application Publication
(10) Pub. No.: US 2019/0157606 A1
(43) Pub. Date: May 23, 2019

(54) DISPLAY DEVICE AND MANUFACTURING METHOD THEREFOR

(71) Applicant: Japan Display Inc., Minato-ku (JP)

(72) Inventor: Kazuhiro ODAKA, Minato-ku (JP)

(73) Assignee: Japan Display Inc., Minato-ku (JP)

(21) Appl. No.: 16/182,652

(22) Filed: Nov. 7, 2018

(30) Foreign Application Priority Data
Nov. 17, 2017 (JP) 2017-221641

(51) Int. Cl. H01L 51/52; H01L 27/32; H01L 51/00; H01L 51/56

(52) U.S. Cl. CPC H01L 51/5209; H01L 27/3246; H01L 27/3276; H01L 51/0097; H01L 2227/323; H01L 51/0023; H01L 51/56; H01L 2251/308; H01L 2251/5338; H01L 51/5215

(57) ABSTRACT

A display device includes a display area with a plurality of pixels arranged therein. Each of the plurality of pixels has a pixel electrode with a three-layer structure including an upper layer, an interlayer, and a lower layer. Each of the upper layer and the lower layer is formed from indium tin oxide or indium zinc oxide. The interlayer is formed from silver. The interlayer has a periphery not extending beyond a periphery of the lower layer. The upper layer covers the interlayer in whole and extends to at least the periphery of the lower layer, in contact with a peripheral edge surface of the interlayer and in contact with the lower layer around the interlayer.

### CROSS-REFERENCE TO RELATED APPLICATION

The present application claims priority from Japanese application JP2017-221641 filed on Nov. 17, 2017, the content of which is hereby incorporated by reference into this application.

### BACKGROUND

### 1. Field

This relates to display devices and manufacturing methods therefor.

### 2. Description of the Related Art

Display devices with a light emitting element such as an organic light emitting diode (OLED) in each pixel are expected for next-generation displays. The light emitting element has a light emitting layer interposed between a pixel electrode (anode) and a common electrode (cathode), for emitting light.

To optimize work function of injecting holes into the light emitting layer, an upper surface of the pixel electrode (surface in contact with the light emitting layer) is covered with an oxide semiconductor film made from indium tin oxide (ITO) or indium zinc oxide (IZO). Additionally, to keep close-fitting property with an inorganic insulation film for an underlayer, another oxide semiconductor film is provided beneath a lower surface of the pixel electrode (surface in contact with the inorganic insulation film) as well (JP 2007-317606A).

While a multilayer film consisting of an IZO film, an Ag film, and an IZO film is etched all at once for forming pixel electrodes, due to difference of etching rates, the Ag film may be recessed, with the IZO film overhanging it like eaves. The overhanging IZO film may cause a luminous dot, when broken, shorting out the anode and the cathode. Or, the Ag film between the IZO films over and under it may be recessed to form a dent, making it likely to form a space formed between the pixel electrode and an insulation layer covering a periphery of the pixel electrode.

### SUMMARY

This is to aim at forming an electrode with a laminate structure in a preferable shape.

A display device may include a display area with a plurality of pixels arranged therein. Each of the plurality of pixels has a pixel electrode with a three-layer structure including an upper layer, an interlayer, and a lower layer. Each of the upper layer and the lower layer is formed from indium tin oxide or indium zinc oxide. The interlayer is formed from silver. The interlayer has a periphery not extending beyond a periphery of the lower layer. The upper layer covers the interlayer in whole and extends to at least the periphery of the lower layer, in contact with a peripheral edge surface of the interlayer and in contact with the lower layer around the interlayer.

The upper layer is in contact with the peripheral edge surface of the interlayer and in contact with the lower layer around the interlayer, making the laminate structure of the electrode in a preferable shape.

A manufacturing method for a display device may include forming a first conductive film from indium tin oxide or indium zinc oxide; forming a second conductive film from silver to be laminated on the first conductive film; forming a lower layer and an interlayer of each of a plurality of pixel electrodes by collective etching of the first conductive film and the second conductive film, with a periphery of the interlayer not extending beyond a periphery of the lower layer; forming a third conductive film from the indium tin oxide or the indium zinc oxide to be laminated on the lower layer and the interlayer; and forming an upper layer of each of the plurality of pixel electrodes by etching of the third conductive film. The upper layer is formed to cover the interlayer in whole and extend to at least the periphery of the lower layer, to be in contact with a peripheral edge surface of the interlayer, and to be in contact with the lower layer around the interlayer.

The upper layer is in contact with the peripheral edge surface of the interlayer and in contact with the lower layer around the interlayer, making the laminate structure of the electrode in a preferable shape.

### BRIEF DESCRIPTION OF THE DRAWINGS

FIG. 1 is a cross-sectional view of a display device in a first embodiment.

FIG. 2 is an enlarged view of a portion II in FIG. 1.

FIGS. 3A-3F are diagrams for explaining a manufacturing method of a display device in the first embodiment.

FIGS. 4A-4F are diagrams for explaining a manufacturing method of a display device in a second embodiment.

### DETAILED DESCRIPTION

Hereinafter, some embodiments will be described with reference to the drawings. Here, the invention can be embodied according to various aspects within the scope of the invention without departing from the gist of the invention and is not construed as being limited to the content described in the embodiments exemplified below.

The drawings are further schematically illustrated in widths, thickness, shapes, and the like of units than actual forms to further clarify description in some cases but are merely examples and do not limit interpretation of the invention. In the present specification and the drawings, the same reference numerals are given to elements having the same functions described in the previously described drawings and the repeated description will be omitted.

Further, in the detailed description, “on” or “under” in definition of positional relations of certain constituents and other constituents includes not only a case in which a constituent is located just on or just under a certain constituent but also a case in which another constituent is interposed between constituents unless otherwise mentioned.

### First Embodiment

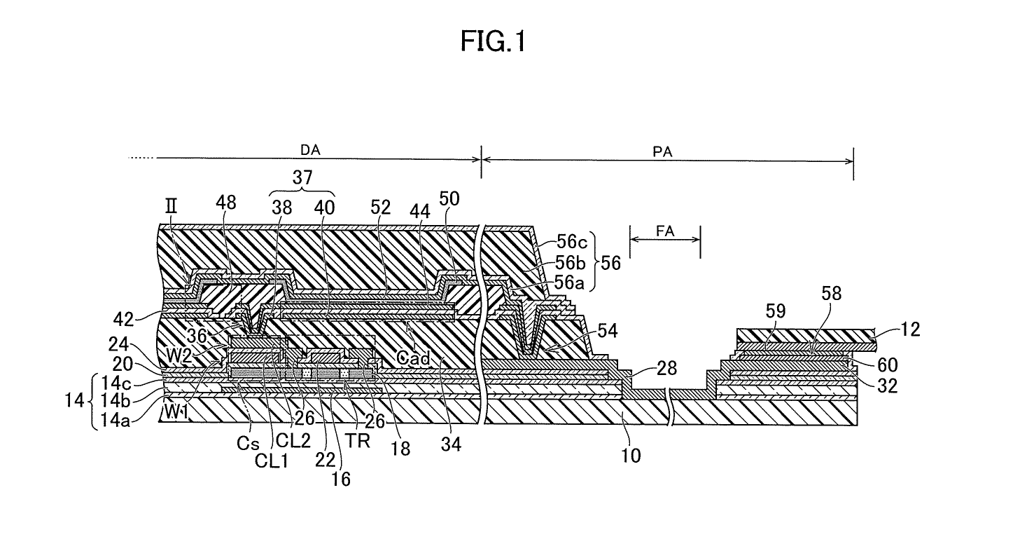

FIG. 1 is a cross-sectional view of a display device in a first embodiment. The display device is an organic electroluminescence (EL) display device. The display device is configured to display a full-color image by forming full-color pixels, each of which consists of unit pixels (sub-pixels) in some colors such as red, green, and blue.

The display device includes a display area DA and a peripheral area PA around the display area DA. The peripheral area PA is outside the display area DA. A flexible printed circuit board (FPC) 12 is connected to the peripheral area PA. The flexible printed circuit board 12 has an integrated circuit (not shown) mounted thereon for controlling an element to display the image.

The substrate 10 (array substrate) and another substrate (unillustrated counter substrate) is made from a material such as polyimide. Or, other resin materials can be used as long as the materials have enough flexibility for a sheet display or a flexible display.

A three-layer laminate structure, consisting of a silicon oxide film 14a, a silicon nitride film 14b, and a silicon oxide film 14c, is on the substrate 10 for an undercoat layer 14. The silicon oxide film 14a in the lowest layer is for improving a close-fitting property with the substrate 10; the silicon nitride film 14b in the middle layer is for a blocking film from external moisture and impurities; the silicon oxide film 14c in the uppermost layer is for another blocking film to prevent hydrogen atoms in the silicon nitride film 14b from diffusing on a side of a semiconductor layer 18 of a thin film transistor TR. Such a structure, however, is not essential. Another layer may be laminated, and a single layer or a double-layer structure is applicable thereto.

An additional film 16 may lie under the undercoat layer 14, corresponding to an area where the thin film transistor TR is formed. The additional film 16 may curb a characteristic change of the thin film transistor TR due to light intrusion from its channel back or may provide the thin film transistor TR with a backgating effect by being formed from a conductive material to apply a certain potential. In this embodiment, after the silicon oxide film 14a is formed, the additional film 16 is formed in an island shape corresponding to an area where the thin film transistor TR is formed, and then the silicon nitride film 14b and the silicon oxide film 14c are laminated, whereby the additional film 16 is sealed in the undercoat layer 14. Alternatively, the undercoat layer 14 may be formed after the additional film 16 is formed on the substrate 10.

The thin film transistor TR is on the undercoat layer 14. A polysilicon thin film transistor is illustrated and only an N-channel transistor is herein shown but a P-channel transistor may be simultaneously formed. The semiconductor layer 18 in the thin film transistor TR has a structure where a low-concentration impurity area is provided between a channel area and a source/drain area. A silicon oxide film is herein used for a gate insulation film 20. A gate electrode 22 is a part of a first trace layer W1 made from MoW. The first trace layer W1 includes a first storage capacitor line CL1 in addition to the gate electrode 22. A part of a storage capacitor Cs is formed between the first storage capacitor line CL1 and the semiconductor layer 18 (source/drain area), with the gate insulation film 20 interposed therebetween.

An interlayer dielectric 24 (silicon oxide film and silicon nitride film) is on the gate electrode 22. At least a part of the interlayer dielectric 24 is removed to make the substrate 10 more flexible and foldable at a folding area FA. Removing the part of the interlayer dielectric 24 exposes the undercoat layer 14, at least apart of which is also removed by patterning. After removing the part of the undercoat layer 14, polyimide constituting the substrate 10 is exposed. The etching of the undercoat layer 14 may partially etch its polyimide surface and reduce its thickness.

A second trace layer W2, which includes portions for the source/drain electrode 26 and a leading line 28, is on the interlayer dielectric 24. A three-layer laminate structure made of Ti, Al, and Ti is herein employed. The first storage capacitor line CL1 (part of the first trace layer W1) and a second storage capacitor line CL2 (part of the second trace layer W2) constitute another portion of the storage capacitor Cs, with the interlayer dielectric 24 interposed therebetween. The leading line 28 extends to an edge of the substrate 10 and has a terminal 32 for being connected to the flexible printed circuit board 12.

A planarization layer 34 covers the source/drain electrode 26 and the leading line 28 (except for some of their portions). Organic materials such as photosensitive acrylic are often used for the planarization layer 34 because of superior surface flatness, compared with inorganic insulation materials formed by chemical vapor deposition (CVD).

The planarization layer 34 is removed at a pixel contact portion 36 and in the peripheral area PA and has an indium tin oxide (ITO) film 37 formed thereon. The indium tin oxide film 37 includes a first transparent conductive film 38 and a second transparent conductive film 40 separated from each other.

The second trace layer W2, which has its surface exposed by removing the planarization layer 34, is covered with the first transparent conductive film 38. A silicon nitride film 42 is on the planarization layer 34, covering the first transparent conductive film 38. The silicon nitride film 42 has an opening at the pixel contact portion 36. A pixel electrode 44 is laminated on and connected to the source/drain electrode 26 through the opening. The pixel electrode 44 is a reflective electrode, with a three-layer laminate structure consisting of an indium zinc oxide (IZO) film, a silver (Ag) film, and an indium zinc oxide film. Instead of the indium zinc oxide film, an indium tin oxide film may be used. The pixel electrode 44 extends laterally from the pixel contact portion 36 to above the thin film transistor TR.

The second transparent conductive film 40 is adjacent to the pixel contact portion 36 and under the pixel electrode 44 (further under the silicon nitride film 42). The second transparent conductive film 40, the silicon nitride film 42, and the pixel electrode 44 overlap with one another, whereby an additional capacitance Cad is formed.

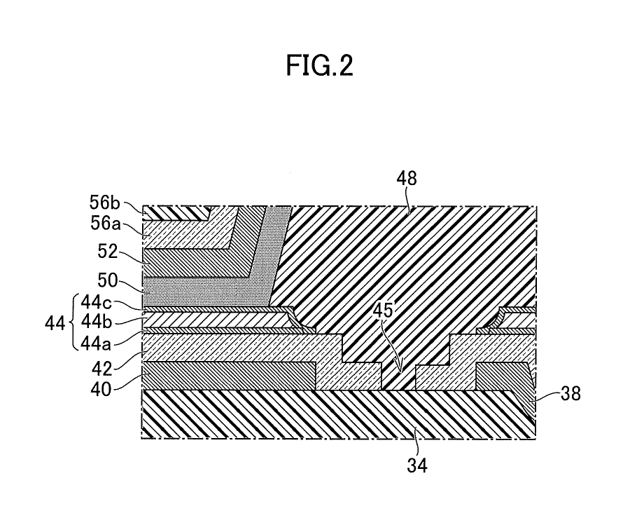

FIG. 2 is an enlarged view of a portion II in FIG. 1. The pixel electrode 44 has a three-layer structure consisting of a lower layer 44a, an interlayer 44b, and an upper layer 44c. The lower layer 44a is made from indium tin oxide (ITO) or indium zinc oxide (IZO). The interlayer 44b is made from silver. The interlayer 44b has a periphery not beyond a periphery of the lower layer 44a. The interlayer 44b has a peripheral edge surface, in a forward tapered shape, which slopes to face obliquely upward. The upper layer 44c is made from indium tin oxide or indium zinc oxide. The upper layer 44c entirely covers the interlayer 44b and extends to at least the periphery of the lower layer 44a. The upper layer 44c extends beyond the periphery of the lower layer 44a. The upper layer 44c is in contact with the peripheral edge surface of the interlayer 44b. The upper layer 44c is in contact with the lower layer 44a around the interlayer 44b. The upper layer 44c is in contact with a peripheral edge surface of the lower layer 44a. In accordance with the embodiment, the upper layer 44c is in contact with the peripheral edge surface of the interlayer 44b and is in contact with the lower layer 44a around the interlayer 44b, making the laminate structure of the electrode in a preferable shape.

An insulation layer 48, which is called a bank (rib) for a partition of adjacent pixel areas, is on the planarization layer 34 and over the pixel contact portion 36, for example. Photosensitive acrylic may be used for the insulation layer 48 just like the planarization layer 34. The insulation layer 48 has an opening for exposing a surface of the pixel electrode 44 as a light emitting region. The opening preferably has an edge in a gently declined shape. A steep shape of the opening edge may cause insufficient coverage of a light emitting layer 50 formed thereon.

The planarization layer 34 and the insulation layer 48 are in contact with each other through an opening in the silicon nitride film 42 between them. This makes it possible to remove moisture and gas desorbed from the planarization layer 34 through the insulation layer 48 during heat treatment after the insulation layer 48 is formed.

A light emitting layer 50 is laminated on the pixel electrode 44. A hole transport layer may be laminated under the light emitting layer 50 or an electron transport layer may be laminated on the light emitting layer 50. These layers may be formed by vapor deposition, by solvent dispersion and application, by selective formation for the pixel electrode 44 (each sub-pixel), or by overall formation over the display area DA. The overall formation may be used for a structure where every sub-pixel emits white light and a desired color wavelength portion thereof passes through a color filter (not shown). In any example, the light emitting layer 50 is on the plurality of pixel electrodes 44. The insulation layer 48 covers a periphery of each pixel electrode 44.

A counter electrode 52 is on the light emitting layer 50. Due to a top emission structure herein employed, the counter electrode 52 is transparent. A Mg layer and an Ag layer may be formed to be a thin film through which outgoing light from the light emitting layer 50 can pass. In comply with the forming order of the light emitting layer 50, the pixel electrode 44 is an anode and the counter electrode 52 is a cathode. The counter electrode 52 is formed over the display area DA, extends to a cathode contact portion 54 next to the display area DA, and is connected to the leading line 28 under the cathode contact portion 54 to be electrically connected to the terminal 32.

A sealing film 56 is on the counter electrode 52. The sealing film 56 may serve to prevent external moisture intrusion into the light emitting layer 50 formed thereunder, necessitating high gas barrier property. A silicon nitride film 56a, an organic resin layer 56b, and a silicon nitride film 56c are laminated to constitute a laminate structure including a silicon nitride film. A silicon oxide film or an amorphous silicon layer may be formed between the silicon nitride films 56a, 56c and the organic resin layer 56b for improving close-fitting property, for example. A cover glass or a touch panel substrate may be provided on the sealing film 56, if necessary. In this case, filler of resin may be used for filling a gap between the sealing film 56 and the cover glass or the touch panel substrate.

External terminals 58 are outside the display area DA. The external terminals 58 may be bonded to a flexible printed circuit board 12 with an anisotropic conductive film 59 interposed therebetween. The external terminals 58 each have a lower layer which may be an edge 32 of a leading line 28. The uppermost layer 60 of each external terminal 58 is made from the same material (ITO or IZO) as the upper layer 44c of the pixel electrode 44. The uppermost layer 60 is provided as a barrier film for not damaging an exposed portion of the edge 32 in the subsequent processes.

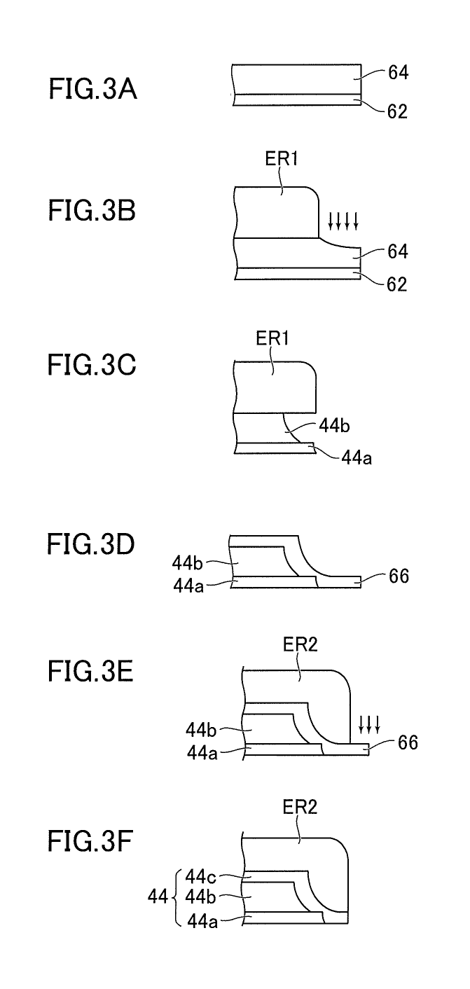

FIGS. 3A-3F are diagrams for explaining a manufacturing method of a display device in the first embodiment. Some layers below the pixel electrode 44 in FIG. 1 are formed in a well-known way. Forming processes of the pixel electrode 44 is explained below.

As shown in FIG. 3A, a first conductive film 62 are formed from indium tin oxide (ITO) or indium zinc oxide (IZO), and a second conductive film 64 is formed from silver and laminated on the first conductive film 62.

As shown in FIG. 3B, an etching resist ER1 is formed and patterned on the second conductive film 64, and the first conductive film 62 and the second conductive film 64 are etched all at once. Such collective etching is wet etching where mixed acid of phosphoric acid, nitric acid, and acetic acid is used.

As shown in FIG. 3C, the lower layer 44a and the interlayer 44b of the pixel electrode 44 are formed by wet etching. Depending on difference of etching rates, the second conductive film 64 is made undercut. This makes the periphery of interlayer 44b not beyond the periphery of the lower layer 44a. Specifically, the periphery of the lower layer 44a is beyond the periphery of the interlayer 44b.

As shown in FIG. 3D, a third conductive film 66 is formed from indium tin oxide (ITO) or indium zinc oxide (IZO) and is laminated on the lower layer 44a and the interlayer 44b.

As shown in FIG. 3E, an etching resist ER2 is formed and patterned on the third conductive film 66, and the third conductive film 66 is etched. The etching of the third conductive film 66 is wet etching where oxalic acid is used.

As shown in FIG. 3F, an upper layer 44c of the pixel electrode 44 is formed by etching the third conductive film 66. The upper layer 44c is formed to entirely cover the interlayer 44b and to extend to at least the periphery of the lower layer 44a. The upper layer 44c is formed to be in contact with the peripheral edge surface of the interlayer 44b. The upper layer 44c is formed to be in contact with the lower layer 44a around the interlayer 44b. Subsequently, the etching resist ER2 is removed.

After the upper layer 44c is formed, as shown in FIG. 1, the insulation layer 48 is formed to cover the periphery of each pixel electrode 44. The light emitting layers 50 are formed on the pixel electrodes 44. The counter electrode 52 is formed on the light emitting layers 50.

In the embodiment, while the pixel electrode 44 is being formed, the external terminals 58 are being formed. The external terminal 58, except for at least the uppermost layer 60, has a base layer which is the edge 32 of the leading line 28, for example. The edge 32 (base layer) is formed of at least one layer of titanium film or formed of a lamination of a titanium film and an aluminum. Forming the edge 32 (base layer) is carried out before forming the first conductive film 62.

During the process of laminating the third conductive film 66 (FIG. 3D), the third conductive film 66 is laminated on the edge 32 (base layer). During the process of forming the upper layer 44c of the pixel electrode 44 (FIG. 3E), the uppermost layer 60 of each external terminal 58 is formed by etching the third conductive film 66.

In the embodiment, after forming and patterning the first conductive film 62 and the second conductive film 64, the third conductive film 66 is formed and patterned. This makes it possible to form the uppermost layer 60 of the external terminals 58 from the third conductive film 66, including none of the first conductive film 62 and the second conductive film 64.

### Second Embodiment

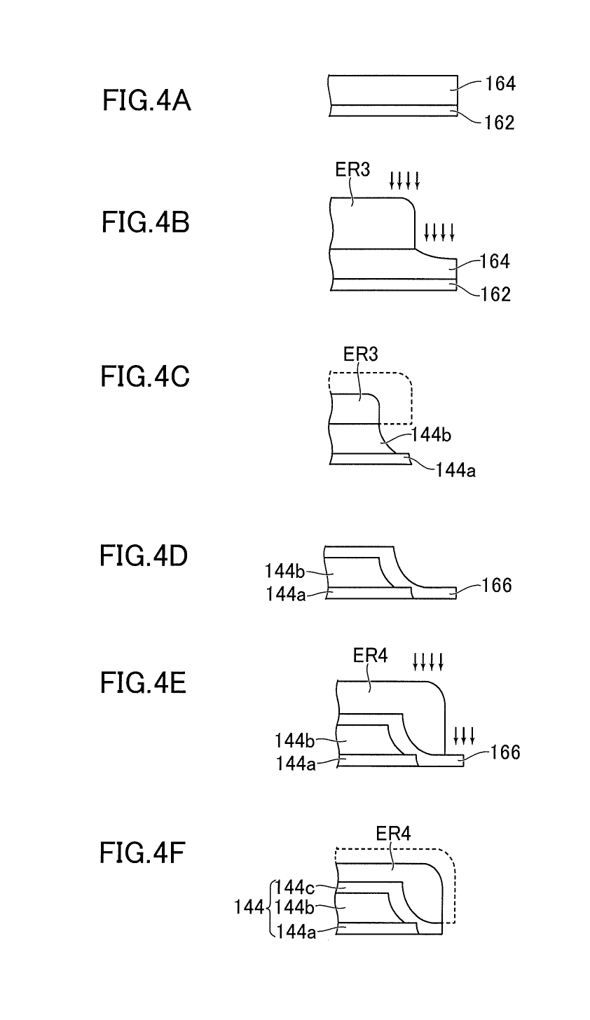

FIGS. 4A-4F are diagrams for explaining a manufacturing method of a display device in a second embodiment. Forming processes of the pixel electrode is explained below.

As shown in FIG. 4A, the first conductive film 162 is formed from indium tin oxide (ITO) or indium zinc oxide (IZO), and the second conductive film 164 is formed from silver and is laminated on the first conductive film 162.

As shown in FIG. 4B, the etching resist ER3 is patterned and formed on the second conductive film 164, and the first conductive film 162 and the second conductive film 164 are etched all at once. Such collective etching is dry etching.

As shown in FIG. 4C, the lower layer 144a and the interlayer 144b of each pixel electrode 144 are formed by dry etching. The dry etching makes the etching resist ER3 recessed and also makes the second conductive film 164 at its edge recessed. Accordingly, the periphery of the interlayer 144b is not beyond the periphery of the lower layer 144a. Specifically, the periphery of the lower layer 144a is beyond the periphery of the interlayer 144b.

As shown in FIG. 4D, the third conductive film 166 is formed from indium tin oxide (ITO) or indium zinc oxide (IZO) and is laminated on the lower layer 144a and the interlayer 144b.

As shown in FIG. 4E, the etching resist ER4 is patterned and formed on the third conductive film 166, and the third conductive film 166 is etched. The etching of the third conductive film 166 is also dry etching.

As shown in FIG. 4F, because of the dry etching herein employed, the etching resist ER4 is made recessed. The upper layer 144c of each pixel electrode 144 is formed by etching the third conductive film 166. The upper layer 144c is formed to entirely cover the interlayer 144b and extend to at least the periphery of the lower layer 144a. The upper layer 144c is formed to be in contact with the peripheral edge surface of the interlayer 144b. The upper layer 144c is formed to be in contact with the lower layer 144a around the interlayer 144b. Subsequently, the etching resist ER4 is removed.

The electronic device is not limited to the organic electroluminescence display device but may be a display device with a light emitting element disposed in each pixel, such as a quantum-dot light emitting diode (QLED), or a liquid crystal display device.

While there have been described what are at present considered to be certain embodiments, it will be understood that various modifications maybe made thereto, and it is intended that the appended claims cover all such modifications as fall within the true spirit and scope of the invention.

What is claimed is:

1. A display device comprising a display area with a plurality of pixels arranged therein, wherein
each of the plurality of pixels has a pixel electrode with a three-layer structure including an upper layer, an interlayer, and a lower layer,
each of the upper layer and the lower layer is formed from indium tin oxide or indium zinc oxide,
the interlayer is formed from silver,
the interlayer has a periphery not extending beyond a periphery of the lower layer, and
the upper layer covers the interlayer in whole and extends to at least the periphery of the lower layer, in contact with a peripheral edge surface of the interlayer and in contact with the lower layer around the interlayer.

2. The display device according to claim 1, wherein the upper layer is in contact with a peripheral edge surface of the lower layer.

3. The display device according to claim 1, wherein the upper layer extends beyond the periphery of the lower layer.

4. The display device according to claim 1, wherein the peripheral edge surface of the interlayer faces obliquely upward.

5. The display device according to claim 1, further comprising:
an insulation layer covering a periphery of the pixel electrode;
a light emitting layer on the pixel electrode; and
a counter electrode on the light emitting layer.

6. The display device according to claim 1, further comprising some external terminals outside the display area, wherein
the uppermost layer of each of the external terminals is made from the same material as the upper layer.

7. A manufacturing method for a display device comprising:
forming a first conductive film from indium tin oxide or indium zinc oxide;
forming a second conductive film from silver to be laminated on the first conductive film;
forming a lower layer and an interlayer of each of a plurality of pixel electrodes by collective etching of the first conductive film and the second conductive film, with a periphery of the interlayer not extending beyond a periphery of the lower layer;
forming a third conductive film from the indium tin oxide or the indium zinc oxide to be laminated on the lower layer and the interlayer; and
forming an upper layer of each of the plurality of pixel electrodes by etching of the third conductive film, wherein
the upper layer is formed to cover the interlayer in whole and extend to at least the periphery of the lower layer, to be in contact with a peripheral edge surface of the interlayer, and to be in contact with the lower layer around the interlayer.

8. The manufacturing method according to claim 7, wherein the collective etching is wet etching in which mixed acid of phosphoric acid, nitric acid, and acetic acid is used.

9. The manufacturing method according to claim 7, wherein the etching of the third conductive film is wet etching in which oxalic acid is used.

10. The manufacturing method according to claim 7, after forming the upper layer, further comprising:
forming an insulation layer to cover a periphery of each of the plurality of pixel electrodes;
forming a light emitting layer on the plurality of pixel electrodes; and
forming a counter electrode on the light emitting layer.

11. The manufacturing method according to claim 7, further comprising forming a base layer of each of external terminals except for at least the uppermost layer thereof, before forming the first conductive film, wherein
the third conductive film is laminated on the base layer in the step of forming the third conductive film, and
the uppermost layer of each of the external terminals is formed by the etching of the third conductive film, in the step of forming the upper layer of each of the plurality of pixel electrodes.

12. The manufacturing method according to claim 11, wherein the base layer is formed to be at least one titanium film or a laminate of a titanium film and an aluminum film, in the step of forming the base layer.
